(19) United States
(12) Patent Application Publication
(10) Pub. No.: US 2022/0372053 A1
(43) Pub. Date: Nov. 24, 2022

(54) STABLE BIS(ALKYL-ARENE) TRANSITION METAL COMPLEXES AND METHODS OF FILM DEPOSITION USING THE SAME

(71) Applicant: L'Air Liquide, Société Anonyme pour l'Etude et l'Exploitation des Procédés Georges Claude, Paris (FR)

(72) Inventors: Rocio Alejandra ARTEAGA MULLER, Yokosuka (JP); Raphael ROCHAT, Yokohama (JP); Julien GATINEAU, San Jose, CA (US); Teruo BEPPU, Yokosuka (JP); Bo PENG, Fremont, CA (US)

(21) Appl. No.: 17/327,045

(22) Filed: May 21, 2021

(51) Int. Cl. C07F 11/00; C23C 16/455; C23C 16/50; C23C 16/06; C23C 16/40; C23C 16/32; C23C 16/34

(52) U.S. Cl. CPC C07F 11/00; C23C 16/45553; C23C 16/45536; C23C 16/50; C23C 16/06; C23C 16/40; C23C 16/32; C23C 16/34

(57) ABSTRACT

Disclosed is a method for forming a metal-containing film on a substrate comprises the steps of:
exposing the substrate to a vapor of a film forming composition that contains a metal-containing precursor; and
depositing at least part of the metal-containing precursor onto the substrate to form the metal-containing film on the substrate through a vapor deposition process,
wherein the metal-containing precursor is a pure M(alkyl-arene)₂, wherein M is Cr, Mo, or W; arene is

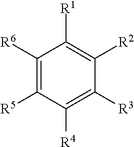

wherein R¹, R², R³, R⁴, R⁵ and R⁶ each is independently selected from H, C₁-C₆ alkyl, C₁-C₆ alkenyl, C₁-C₆ alkylphenyl, C₁-C₆ alkenylphenyl, or —SiXR⁷R⁸, wherein X is selected from F, Cl, Br, I, and R⁷, R⁸ each are selected from H, C₁-C₆ alkyl, C₁-C₆ alkenyl.

### TECHNICAL FIELD

The present invention relates to transition metal-containing complexes and methods for forming transition metal-containing films using the same on a substrate via a vapor deposition process, in particular, to bis(alkyl-arene) transition metal complexes and methods of using the same to form the transition metal-containing films.

### BACKGROUND

Molybdenum is a low-resistivity refractory metal that has been used in microelectronic devices, e.g., as an alternative to tungsten. Molybdenum has a high melting point, high thermal conductivity, a low coefficient of thermal expansion, and low electrical resistivity. Molybdenum or molybdenum-containing films have been used or proposed to use as a diffusion barrier, electrode, photomask, interconnect, or as a low-resistivity gate structure. Molybdenum is a candidate for replacing tungsten used in memory chips, logic chips, and other devices that include polysilicon-metal gate electrode structures. A thin film that contains molybdenum can also be used in some organic light emitting diodes, liquid crystal displays, and in thin film solar cells and photovoltaics.

Gribov et al., (Doklady Akademii Nauk SSSR, Volume 194, Issue 3, Pages 580-582, 1970) describes films were obtained in pyrolysis mode at high temperature with an M(arene)₂ and films had some carbon in it so that pure Mo films were not obtained even at high temperatures. The described films were deposited at 10⁻² Torr and 400-700° C. from Cr(C₆H₆)₂, Cr(MePh)₂, Cr(EtPh)₂, Cr(Me₂C₆H₄)₂, bis(mesitylene)chromium, bis-(biphenyl)chromium, and their iodides, from (aniline)-, (dimethylaniline)- and (mesitylene)tricarbonylchromium, (mesitylene) tricarbonylmolybdenum, and bis(ethylbenzene)molybdenum on preheated samples.

Pure Mo films are desired in the semiconductor industry. However, a very few organometallic Mo containing complexes available for forming the pure Mo films have low impurity levels. For example, one commercial product, Mo(Et-benzene)₂, (US2019/0226086A) is available as a mixture only. It is a requirement for the semiconductor industry to use complex products with a high purity (at least >99% or more). US2019/0226086A claims the usage of bis(alkyl-arene) molybdenum molecules for the deposition of Mo containing films on a substrate, solely describing the use of Mo(Et-benzene)₂ for the deposition of molybdenum carbide films. Pure Mo films cannot be obtained because of the poor stability of the compound. The commercially available compound is usually supplied as a mixture of isomers.

Metal arene complexes have been investigated as sources for the deposition of pure metallic films. Such as, US2019/0226086, US20200115798 and US20190390340 disclose Bis(alkyl-arene) molybdenum complexes as suitable complexes for vapor deposition of molybdenum.

US 2019/0390340 to Yu et at discloses a metal deposition method comprising sequentially exposing a substrate to a metal precursor and an alkyl halide to form a metal film, the metal precursor having a decomposition temperature above the deposition temperature, and the alkyl halide comprising carbon and halogen, the halogen comprising bromine or iodine, and the metal is selected from molybdenum, ruthenium, cobalt, copper, platinum, nickel or tungsten.

In order to obtain a product suitable to use as a semiconductor precursor, high purity, sufficient thermal stability under desired usage conditions are required.

### SUMMARY

Disclosed is a method for forming a metal-containing film on a substrate, the method comprising the steps of:
exposing the substrate to a vapor of a film forming composition that contains a metal-containing precursor; and
depositing at least part of the metal-containing precursor onto the substrate to form the metal-containing film on the substrate through a vapor deposition process,
wherein the metal-containing precursor is a pure M(alkyl-arene)₂, wherein M is Cr, Mo, or W; arene is

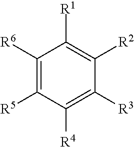

wherein R¹, R², R³, R⁴, R⁵ and R⁶ each is independently selected from H, C₁-C₆ alkyl, C₁-C₆ alkenyl, C₁-C₆ alkylphenyl, C₁-C₆ alkenylphenyl, or —SiXR⁷R⁸, wherein X is selected from F, Cl, Br, I, and R⁷, R⁸ each are selected from H, C₁-C₆ alkyl, C₁-C₆ alkenyl.

The disclosed methods may include one or more of the following aspects:
the pure M(alkyl-arene)₂ precursor being selected from Mo(toluene)₂, Mo(Et-benzene)₂, Mo(o-xylene)₂, Mo(m-xylene)₂, Mo(p-xylene)₂, Mo(mesitylene)₂, Mo(ally-benzene)₂, Mo(1,3,5-Et₃-benzene)₂, Mo[Me₂Si—Cl)-benzene]₂, Mo(styrene)₂, Mo(tetramethylsilane-benzene)₂, Mo[(4-vinylphenyl)benzene]₂, Mo(benzene)(Et-benzene), Mo(durene)₂, Mo(C₆H₅—²H)₂;
the pure M(alkyl-arene)₂ precursor being selected from Cr(toluene)₂, Cr(Et-benzene)₂, Cr(o-xylene)₂, Cr(m-xylene)₂, Cr(p-xylene)₂, Cr(mesitylene)₂, Cr(ally-benzene)₂, Cr(1,3,5-Et₃-benzene)₂, Cr[(Me₂Si—Cl)-benzene]₂, Cr(styrene)₂, Cr(tetramethylsilane-benzene)₂, Cr[(4-vinylphenyl)benzene]₂, Cr(benzene)(Et-benzene), Cr(durene)₂, Cr(C₆H₅—²H)₂;
the pure M(alkyl-arene)₂ precursor being selected from W(toluene)₂, W(Et-benzene)₂, W(o-xylene)₂, W(m-xylene)₂, W(p-xylene)₂, W(mesitylene)₂, W(ally-benzene)₂, W(1,3,5-Et₃-benzene)₂, W[(Me₂Si—Cl)-benzene]₂, W(styrene)₂, W(tetramethylsilane-benzene)₂, W[(4-vinylphenyl)benzene]₂, W(benzene)(Et-benzene), W(durene)₂, or W(C₆H₅—²H)₂;
the pure M(alkyl-arene)₂ precursor being Mo(m-xylene)₂;
the pure M(alkyl-arene)₂ precursor being Mo(toluene)₂;
the pure M(alkyl-arene)₂ precursor being Mo(1,3,5-Et₃-benzene)₂;
the pure M(alkyl-arene)₂ precursor being Mo(mesitylene)₂;
the pure M(alkyl-arene)₂ precursor referring to a M(alkyl-arene)₂ for which the concentration of each of its isomers or any other impurities is below around 15%, preferably below around 10%, more preferably below around 5%, and even more preferably below around 1%;
the film forming composition having a purity ranging from approximately 85% w/w to approximately 100% w/w;
the film forming composition having a purity ranging from approximately 95% w/w to approximately 100% w/w;
the film forming composition having a purity ranging from approximately 99% w/w to approximately 99.999% w/w;
the purity of the pure M(alkyl-arene)₂ precursor ranging from approximately 85% w/w to approximately 100% w/w;
the purity of the pure M(alkyl-arene)₂ precursor ranging from approximately 95% w/w to approximately 100% w/w;
the purity of the pure M(alkyl-arene)₂ precursor ranging from approximately 99% w/w to approximately 99.999% w/w;
the purity of the pure M(alkyl-arene)₂ precursor being greater than 85% w/w;
the pure M(alkyl-arene)₂ precursor having a high thermal stability;
a decomposition temperature of the pure M(alkyl-arene)₂ being higher than approximately 235° C.;
a decomposition temperature of the pure M(alkyl-arene)₂ being higher than approximately 240° C.;
a deposition temperature ranging from approximately 20° C. and approximately 600° C.;
a deposition temperature ranging from approximately 20° C. and approximately 550° C.;
a deposition temperature ranging from approximately 200° C. and approximately 600° C.;
a deposition pressure ranging from a vacuum to ambient pressure;
a deposition pressure ranging from about 0.001 mTorr to about 760 Torr
the metal-containing film being a pure metal, metal carbide, metal oxide, metal nitride, metal silicide film or combinations thereof;
the metal-containing film being a pure metal film;
the metal-containing film being a metal carbide film;
the metal-containing film being a metal oxide film;
the metal-containing film being a metal nitride film;
the metal-containing film being a metal silicide film;
the metal-containing film being a molybdenum film;
the metal-containing film being a molybdenum carbide film;
the metal-containing film being a molybdenum oxide film;
the metal-containing film being a molybdenum nitride film;
the metal-containing film being a molybdenum silicide film;
the film forming composition including an inert carrier gas;
the inert carrier gas being selected from N₂, He, Ne, Ar, Kr, Xe, or combinations thereof;
the inert carrier gas being N₂ or Ar;
further comprising the step of exposing the substrate to a co-reactant;
further comprising the step of plasma treating the co-reactant;
the co-reactant being halosilane, polyhalodisilane (halo=F, Cl, Br, I), organohalide selected from SiH₂Cl₂, SiH₂I₂, SiHCl₃, SiCl₄, SiBr₄, Si₂Cl₆, Si₂Br₆, Si₂HCl₅, Si₃Cl₈, CH₂I₂, CH₃I, C₂H₅I, C₄H₉I, or C₆H₅I;
the co-reactant being selected from O₂, O₃, H₂O, H₂O₂, N₂O, NO, NO₂, O. or OH. radicals, or mixtures thereof;
the co-reactant being selected from H₂, NH₃, N₂H₄, Me-N₂H₄, Me₂N₂H₂, SiH₄, Si₂H₆, Si₃H₈, Si₄H₁₀, SiH₂Me₂, SiH₂Et₂, N(SiH₃)₃, NH₃ radicals, H₂ radicals, or combination thereof;
wherein the co-reactant being selected from NH₃, NO, N₂O, hydrazines, N₂ plasma, N₂/H₂ plasma, NH₃ plasma, amines and combinations thereof;
the co-reactant being O₂;
the co-reactant being NH₃;
the co-reactant being H₂;
the vapor deposition process being a ALD process, a CVD process or a combination thereof;
the vapor deposition process being a ALD process;
the vapor deposition process being a CVD process;
the vapor deposition process being a PEALD process;
the substrate being selected from a Si-containing substrate, a metal substrate, a metal-containing substrate or a powder substrate;
the substrate being a Si-containing substrate;
the substrate being a metal substrate;
the substrate being a metal-containing substrate;
the substrate being a powder substrate;
the powder substrate including a non-limiting number of powder materials include NMC (Lithium Nickel Manganese Cobalt Oxide), LCO (Lithium Cobalt Oxide), LFP (Lithium Iron Phosphate), and other battery cathode materials; and
the powder substrate being activated carbon.

### Notation and Nomenclature

The following detailed description and claims utilize a number of abbreviations, symbols, and terms, which are generally well known in the art. Certain abbreviations, symbols, and terms are used throughout the following description and claims, and include:

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 25° C.

The term “pure” refers to a product for which the concentration of each of its isomers or any other impurities is below around 15%, preferably below around 10%, more preferably below around 5%, and even more preferably below around 1%.

The term “high thermal stability” refers to the property of a product to evaporate smoothly in thermogravimetry analysis, without exhibiting a “tail” or generating residual amount above 200° C. herein, more preferably the residual amount is below about 5% at 300° C., more preferably below about 2% at 300° C., or a product whose DSC analysis exhibits an onset of decomposition temperature higher than that of commercially available products, and more preferably higher than 240° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. The substrate may also be a powder, such as the powder used in rechargeable battery technology. A non-limiting number of powder materials include NMC (Lithium Nickel Manganese Cobalt Oxide), LCO (Lithium Cobalt Oxide), LFP (Lithium Iron Phosphate), and other battery cathode materials. Exemplary powder substrate also includes activated carbon.

The term “wafer” or “patterned wafer” refers to a wafer having a stack of films on a substrate and at least the top-most film having topographic features that have been created in steps prior to the deposition of the indium containing film.

The term “aspect ratio” refers to a ratio of the height of a trench (or aperture) to the width of the trench (or the diameter of the aperture).

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line. Throughout the specification and claims, the wafer and any associated layers thereon are referred to as substrates.

Note that herein, the terms “aperture”, “via”, “hole” and “trench” may be used interchangeably to refer to an opening formed in a semiconductor structure.

As used herein, the abbreviation “NAND” refers to a “Negative AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “deposition temperature” and “substrate temperature” may be used interchangeably. It is understood that a substrate temperature may correspond to, or be related to a deposition temperature, and that the deposition temperature may refer to the substrate temperature.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

The standard abbreviations of the elements from the periodic table of elements are used herein. It should be understood that elements may be referred to by these abbreviations (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to any propyl group (i.e., n-propyl or isopropyl); the abbreviation “iPr” refers to an isopropyl group; the abbreviation “Bu” refers to any butyl group (n-butyl, iso-butyl, tent-butyl, sec-butyl); the abbreviation “tBu” refers to a tert-butyl group; the abbreviation “sBu” refers to a sec-butyl group; the abbreviation “iBu” refers to an iso-butyl group; the abbreviation “Ph” refers to a phenyl group; the abbreviation “Amy” refers to any amyl group (iso-amyl, sec-amyl, tert-amyl), the abbreviation “Cy” refers to a cyclic hydrocarbon group (cyclobutyl, cyclopentyl, cyclohexyl, etc.); the abbreviation “Ar” refers to an aromatic hydrocarbon group (phenyl, xylyl, mesityl, etc.).As used in the disclosed embodiments, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas,

As used herein, the abbreviation “m-” refers to “meta-”. For example, m-xylene refers to meta-xylene. The abbreviation “o-” refers to “ortho-”. For example, o-xylene refers to ortho-xylene. The abbreviation “p-” refers to “para-”. For example, p-xylene refers to para-xylene.

Ranges may be expressed herein as from about one particular value, and/or to about another particular value. When such a range is expressed, it is to be understood that another embodiment is from the one particular value and/or to the other particular value, along with all combinations within said range. Any and all ranges recited in the disclosed embodiments are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

“Comprising” in a claim is an open transitional term which means the subsequently identified claim elements are a nonexclusive listing i.e. anything else may be additionally included and remain within the scope of “comprising.” “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or dear from context to be directed to a singular form.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is TGA of Mo(ethyl-benzene)₂;

FIG. 2 is DSC of Mo(ethyl-benzene)₂;

FIG. 3 is ⁹⁵Mo NMR results for Mo(ethyl-benzene)₂;

FIG. 4 is atmospheric TG analysis of Mo(mesitylene)₂;

FIG. 5 is DSC of Mo(mesitylene)₂;

FIG. 6 is atmospheric TG analysis of Mo(1,3,5-Et₃-benzene)₂;

FIG. 7 is DSC of Mo(1,3,5-Et3-benzene)₂;

FIG. 8 is atmospheric TG analysis of Mo(m-xylene)₂;

FIG. 9 is DSC of Mo(m-xylene)₂;

FIG. 10 is atmospheric TG analysis of Mo(toluene)₂;

FIG. 11 is DSC of Mo(toluene)₂;

FIG. 12 is atomic profile of deposited file by XPS of chemical vapor deposition of Mo(m-xylene)₂;

FIG. 13 is SEM data of pyrolysis deposition of Mo(m-xylene)₂;

FIG. 14 is atomic profile of deposited film by XPS of chemical vapor deposition of Mo(m-xylene)₂ with H₂; and

FIG. 15 is SEM data of chemical vapor deposition of Mo(m-xylene)₂ with H₂.

### DESCRIPTION OF PREFERRED EMBODIMENTS

Disclosed are metal-containing film-forming compositions comprising bis(alkyl-arene) metal-containing precursors, M(alkyl-arene)₂, where M is Cr, Mo, W, etc., and methods of using the same to deposit metal-containing films using ALD, CVD, SOD, etc., for manufacturing semiconductors, photovoltaics, LCD-TFT, flat panel-type devices, refractory materials, or aeronautics. In particular, the disclosure relates to CVD and ALD processes for deposition of metal-containing films.

The disclosed metal-containing precursors may be pure M(alkyl-arene)₂, wherein M is Cr, Mo, or W; arene is

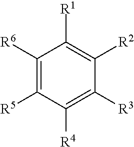

wherein R¹, R², R³, R⁴, R⁵ and R⁶ each is independently selected from H, C₁-C₆ alkyl, C₁-C₆ alkenyl, C₁-C₆ alkylphenyl, C₁-C₆ alkenylphenyl, —SiXR⁷R⁸, wherein X is selected among F, Cl, Br, I, and R⁷, R⁸ each are selected among H, C₁-C₆ alkyl, C₁-C₆ alkenyl.

The term “pure” in “pure M(alkyl-arene)₂” refers to a product for which the concentration of each of its isomers or any other impurities is below around 15%, preferably below around 10%, more preferably below around 5%, and even more preferably below around 1%.

In one embodiment, the disclosed Metal-containing film forming composition contains less than 15% w/w, more preferably less than 10% w/w, and even more preferably less than 1% w/w of any of its undesired species including minor isomers, reactants, or other reaction products, which may provide better process repeatability.

Purity of the disclosed metal-containing film forming composition is greater than 85% w/w (i.e., 85.0% w/w to 100.0% w/w), preferably greater than 95% w/w (i.e., 95.0% w/w to 100.0% w/w), and more preferably greater than 99% w/w (i.e., 99.0% w/w to approximately 99.999% w/w or 99.0% w/w to 100.0% w/w). In addition purity of the disclosed metal-containing precursors, pure M(alkyl-arene)₂, is greater than 85% w/w (i.e., 85.0% w/w to 100.0% w/w), preferably greater than 95% w/w (i.e., 95.0% w/w to 100.0% w/w), and more preferably greater than 99% w/w (i.e., 99.0% w/w to approximately 99.999% w/w or 99.0% w/w to 100.0% w/w). One of ordinary skill in the art will recognize that the purity may be determined by NMR spectroscopy and gas or liquid chromatography with mass spectrometry. The disclosed metal-containing film forming compositions may contain any of the following impurities; pyrazoles; pyridines; alkylamines; alkylimines; THF; ether; pentane; cyclohexane; heptanes; benzene; toluene; chlorinated metal compounds; lithium, sodium, potassium pyrazolyl. The total quantity of these impurities is preferably below 5% w/w (i.e., 0.0% w/w to 5.0% w/w), preferably below 2% w/w (i.e., 0.0% w/w to 2.0% w/w), and more preferably below 1% w/w (i.e., 0.0% w/w to 1.0% w/w). The disclosed film forming composition may be purified by recrystallization, sublimation, distillation, and/or passing the gas liquid through a suitable adsorbent, such as 4 Å molecular sieves.

Purification of the disclosed film forming composition may also result in metal impurities each range independently at the 0 ppbw to 1 ppmw, preferably approximately 0 to approximately 500 ppbw (part per billion weight) level, more preferably from approximately 0 ppbw to approximately 100 ppbw. These metal or metalloid impurities include, but are not limited to, Aluminum(Al), Arsenic(As), Barium(Ba), Beryllium(Be), Bismuth(Bi), Cadmium(Cd), Calcium(Ca), Chromium(Cr), Cobalt(Co), Copper(Cu), Gallium(Ga), Germanium (Ge), Hafnium(Hf), Zirconium(Zr), Iron(Fe), Lead(Pb), Lithium(Li), Magnesium(Mg), Manganese(Mn), Nickel(Ni), Potassium(K), Sodium(Na), Strontium(Sr), Thorium(Th), Tin(Sn), Titanium(Ti), Uranium(U), Vanadium(V) and Zinc(Zn).

The disclosed M(alkyl-arene)₂ precursors may include Mo(toluene)₂, Mo(Et-benzene)₂, Mo(o-xylene)₂, Mo(m-xylene)₂, Mo(p-xylene)₂, Mo(mesitylene)₂, Mo(ally-benzene)₂, Mo(1,3,5-Et₃-benzene)₂, Mo[(Me₂Si—Cl)-benzene]₂, Mo(styrene)₂, Mo(tetramethylsilane-benzene)₂, Mo[(4-vinylphenyl)benzene]₂, Mo(benzene)(Et-benzene), Mo(durene)₂, Mo(C₆H₅—²H)₂, Cr(toluene)₂, Cr(Et-benzene)₂, Cr(o-xylene)₂, Cr(m-xylene)₂, Cr(p-xylene)₂, Cr(mesitylene)₂, Cr(ally-benzene)₂, Cr(1,3,5-Et₃-benzene)₂, Cr[(Me₂Si—Cl)-benzene]₂, Cr(styrene)₂, Cr(tetramethylsilane-benzene)₂, Cr[(4-vinylphenyl)benzene]₂, Cr(Benzene)(Et-benzene), Cr(durene)₂, Cr(C₆H₅—²H)₂, W(toluene)₂, W(Et-benzene)₂, W(o-xylene)₂, W(m-xylene)₂, W(p-xylene)₂, W(mesitylene)₂, W(ally-benzene)₂, W(1,3,5-Et₃-benzene)₂, W[(Me₂Si—Cl)-benzene]₂, W(styrene)₂, W(tetramethylsilane-benzene)₂, W[(4-vinylphenyl)benzene]₂, W(Benzene)(Et-benzene), W(durene)₂, or W(C₆H₅—²H)₂.

The disclosed metal-containing precursors may have a high thermal stability and may be used for forming high-speed, high sensitivity semiconductor films, e.g. in CMOS systems, 3D NAND Channel or in photodetectors. The disclosed metal-containing precursors and the disclosed film forming compositions are suitable to deposit the corresponding element-containing films and its related use for deposition of the corresponding element-containing films. The disclosed films may be deposited uniformly on flat wafers or on patterned wafers, or in a “gap-fill” or “bottom-up gap-fill” approach.

Also disclosed are methods of using the disclosed metal-containing precursors for vapor deposition methods. The disclosed methods provide for the use of the metal-containing precursors for deposition of metal-containing films. The disclosed methods may be useful in the manufacture of semiconductor, photovoltaic, LCD-TFT, or flat panel type devices. The disclosed method includes: providing a substrate; providing a vapor including at least one of the disclosed metal-containing precursors; exposing the substrate to the vapor of a film forming composition that contains a metal-containing precursor; and depositing at least part of the metal-containing precursor onto the substrate to form the metal-containing film on the substrate through a vapor deposition process.

The vapor of the metal-containing precursor is introduced into a reaction chamber containing at least one substrate. The temperature and the pressure within the reaction chamber and the temperature of the substrate are held at conditions suitable for vapor deposition (e.g., ALD and CVD) of at least part of the metal-containing precursor onto the substrate, In other words, after the introduction of the vaporized precursor into the chamber, conditions within the chamber are adjusted such that at least part of the vaporized precursor is deposited onto the substrate to form the metal-containing film. One of ordinary skill in the art will recognize that “at least part of the precursor is deposited” means that some or all of the precursor reacts with or adheres to the substrate. Herein, a co-reactant may also be used to help in formation of the Metal-containing layer, which is described below.

The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. All of these exemplary reaction chambers are capable of serving as CVD or ALD reaction chambers. The reaction chamber may be maintained at a pressure ranging from a vacuum to ambient pressure, for example, from about 0.001 mTorr to about 760 Torr. The pressure within the reaction chamber is a deposition pressure, In addition, the temperature within the reaction chamber may range from about 20° C. to about 600° C. One of ordinary skill in the art will recognize that the temperature may be optimized through mere experimentation to achieve the desired result.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 20° C. to approximately 600° C., When a plasma deposition process is utilized, a deposition temperature may range from approximately 20° C. to approximately 550° C. Alternatively, when a thermal process is performed, the deposition temperature may range from approximately 200° C. to approximately 600° C.

Alternatively, the substrate may be heated to a sufficient temperature to obtain the desired metal-containing film at a sufficient growth rate and with desired physical state and composition. A non-limiting exemplary temperature range to which the substrate may be heated includes from 20° C. to 600° C. Preferably, the temperature of the substrate remains less than or equal to 500° C. Note that herein, the “deposition temperature” and “substrate temperature” may be used interchangeably. It is understood that a substrate temperature may correspond to, or be related to a deposition temperature, and that the deposition temperature may refer to the substrate temperature. When the reactor reaches to a thermal equilibrium, the temperature of the reactor wall may be the same as the deposition temperature and the substrate temperature.

Decomposition temperatures of the disclosed metal-containing precursors are higher than approximately 235° C., more preferably higher than approximately 240° C., which may be found from the examples that follow. The disclosed metal-containing precursors have a high thermal stability. The term “high thermal stability” refers to the property of a product of M(alkyl-arene)₂ to evaporate smoothly in thermogravimetry analysis (TGA), without exhibiting a “tail” or generating residual amount above 200° C., more preferably the residual amount is below about 5% at 300° C., more preferably below about 2% at 300° C., or a product of M(alkyl-arene)2 whose DSC analysis exhibits an onset of decomposition temperature higher than that of commercially available products (around 235° C.), and more preferably higher than approximately 240° C.

The type of substrate upon which the metal-containing film will be deposited may vary depending on the final use intended. In some embodiments, the substrate may be a patterned photoresist film made of hydrogenated carbon, for example CHₓ, wherein x is greater than zero. In some embodiments, the substrate may be chosen from oxides which are used as dielectric materials in MIM, DRAM, or FeRam technologies (for example, ZrO₂ based materials, HfO₂ based materials, TiO₂ based materials, rare earth oxide based materials, ternary oxide based materials, etc.) or from nitride-based films (for example, TaN) that are used as an oxygen barrier between copper and the low-k layer. Other substrates may be used in the manufacture of semiconductors, photovoltaics, LCD-TFT, or flat panel devices. Examples of such substrates include, but are not limited to, solid substrates such as metal nitride containing substrates (for example, TaN, TiN, WN, TaCN, TiCN, TaSiN, and TiSiN); insulators (for example, SiO₂, Si₃N₄, SiON, HfO₂, Ta₂O₅, ZrO₂, TiO₂, Al₂O₃, and barium strontium titanate); or other substrates that include any number of combinations of these materials. The actual substrate utilized may also depend upon the specific precursor embodiment utilized. In many instances though, the preferred substrate utilized will be selected from hydrogenated carbon, TiN, strontium ruthenium oxide (SRO), Ru, and Si type substrates, such as polysilicon or crystalline silicon substrates. The substrate may also be a powder, such as the powder used in rechargeable battery technology. A non-limiting number of powder materials include NMC (Lithium Nickel Manganese Cobalt Oxide), LCO (Lithium Cobalt Oxide), LIP (Lithium Iron Phosphate), and other battery cathode materials. Exemplary powder substrate also includes activated carbon.

The substrate may be patterned to include vias or trenches having high aspect ratios. For example, a conformal Metal-containing film, such as SiO₂, may be deposited using any ALD technique on a through silicon via (TSV) having an aspect ratio ranging from approximately 20:1 to approximately 100:1.

The Metal-containing film forming compositions may be supplied either in neat form or in a blend with a solvent suitable for vapor deposition, such as toluene, ethyl benzene, xylene, mesitylene, decane, dodecane, octane, hexane, pentane, tertiary amines, acetone, tetrahydrofuran, ethanol, ethylmethylketone, 1,4-dioxane, or others. Alternatively, the Metal-containing film forming composition may comprise a solvent suitable for casting deposition, such as naphtha, methylisobutylketone (MIBK), n-methylisobutylketone (NMIBK), or combinations thereof. One of ordinary skill in the art will recognize that the casting deposition solution may further comprise pH regulators or surfactants. The disclosed precursors may be present in varying concentrations in the solvent. For example, the resulting concentration of the vapor deposition solution may range from approximately 0.01 M to approximately 2 M. One of ordinary skill in the art will recognize that the molarity of the casting deposition solution is directly proportional to the desired film thickness and may adjust the molarity accordingly.

For vapor deposition, the neat or blended metal-containing precursors are introduced into a reactor in vapor form by conventional means, such as tubing and/or flow meters. The precursor in vapor form may be produced by vaporizing the neat or blended precursor solution through a conventional vaporization step such as direct vaporization, distillation, by bubbling, or by using a sublimator such as the one disclosed in PCT Publication WO2009/087609 to Xu et al. The neat or blended precursor may be fed in liquid state to a vaporizer where it is vaporized before it is introduced into the reactor. Alternatively, the neat or blended precursor may be vaporized by passing a carrier gas into a container containing the precursor or by bubbling of the carrier gas into the precursor. The carrier gas may include, but is not limited to, N₂, He, Ne, Ar, Kr, Xe, and mixtures thereof. Bubbling with a carrier gas may also remove any dissolved oxygen present in the neat or blended precursor solution. The carrier gas and precursor are then introduced into the reactor as a vapor.

If necessary, the container containing the disclosed film forming composition may be heated to a temperature that permits the metal-containing precursor to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of metal-containing precursor vaporized.

The reactor may be any enclosure chamber within a device in which deposition methods take place such as without limitation, a parallel-plate type reactor, a cold-wall type reactor, a hot-wall type reactor, a single-wafer reactor, a multi-wafer reactor, other types of deposition systems under conditions suitable to cause the compounds to react and form the layers. One of ordinary skill in the art will recognize that any of these reactors may be used for either ALD or CVD deposition processes.

In addition to the disclosed metal-containing precursor, the co-reactant may be introduced into the reactor for forming the metal-containing films. When a target deposited film is a dielectric film, the co-reactant may be an oxidizing gas such as one of O₂, O₃, H₂O, H₂O₂, NO, N₂O, NO₂, oxygen containing radicals such as O. or OH.; NO; NO₂; alcohol, silanols, aminoalcohols, carboxylic acids such as formic acid, acetic acid, propionic acid; radical species of NO, NO₂, or the carboxylic acids; para-formaldehyde; and mixtures thereof. Preferably, the oxidizing agent is selected from the group consisting of O₂, O₃, H₂O, H₂O₂, N₂O, NO, NO₂, oxygen containing radicals thereof such as O. or OH., or mixtures thereof. Preferably, when an ALD process is performed, the co- reactant is plasma treated oxygen, ozone, or combinations thereof, When an oxidizing gas is used as the co-reactant, the resulting metal containing film will also contain oxygen.

Alternatively, when the target is a conductive film, the co-reactant may be a reducing agent such as one of H₂, NH₃, (SiH₃)₃N, hydridosilanes (such as SiH₄, Si₂H₆, Si₃H₈, Si₄H₁₀, Si₅H₁₀, Si₆H₁₂), chlorosilanes and chloropolysilanes (such as SiHCl₃, SiH₂Cl₂, SIH₃Cl, Si₂Cl₆, Si₂HCl₅, Si₃Cl₈), alkylsilanes (such as (CH₃)₂SiH₂, (C₂H₅)₂SiH₂, (CH₃)SiH₃, (C₂H₅)SiH₃), hydrazines (such as N₂H₄, MeHNNH₂, MeHNNHMe), organic amines(such as N(CH₃)H₂, N(C₂H₅)H₂, N(CH₃)₂H, N(C₂H₅)₂H, N(CH₃)₃, N(C₂H₅)₃, (SiMe₃)₂NH), pyrazoline, pyridine, B-containing molecules (such as B₂H₆, 9-borabicyclo[3,3,1]none, trimethylboron, triethylboron, borazine), alkyl metals (such as trimethylaluminum, triethylaluminum, dimethylzinc, diethylzinc), radical species thereof, and mixtures thereof. The co-reactant may be a primary amine, a secondary amine, a tertiary amine, trisilylamine, radicals thereof, and mixtures thereof. Preferably, the reducing agent is H₂, NH₃, N₂H₄, Me-N₂H₄, Me₂N₂H₂, SiH₄, Si₂H₆, Si₃H₈, Si₄H₁₀, SiH₂Me₂, SiH₂Et₂, N(SiH₃)₃, NH₃ radicals, H₂ radicals, or combination thereof. When a reducing agent is used, the resulting metal-containing film may be a pure metal, metal carbide, metal oxide, metal nitride, metal silicide film or combinations thereof. When an N-containing reducing agent is used, the resulting metal-containing film will also contain nitrogen.

Additionally, the co-reactant may be a halosilane, polyhalodisilane (halo=F, Cl, Br, I), or organohalide, such as SiH₂Cl₂, SiH₂I₂, SiHCl₃, SiCl₄, SiBr₄, Si₂Cl₆, Si₂Br₆, Si₂HCl₅, Si₃Cl₈, CH₂I₂, CH₃I, C₂H₅I, C₄H₉I, C₆H₅I, and one or more reactant gases to form metal-containing films, such as pure metal, and metal carbide films. The halide-containing co-reactants, such as, CH₂I₂, CH₃I, C₂H₅I, C₄H₉I, C₆H₅I, help catalyze product decomposition and get gap fill or bottom up gap fill.

Furthermore, the co-reactant may be treated by plasma, in order to decompose the reaction gas into its radical form, at least one of H₂, N₂ and O₂ may be utilized as a hydrogen, nitrogen or oxygen source gas, respectively, when treated with plasma. The plasma source may be a N₂ plasma, N₂/He plasma, N₂/Ar plasma, NH₃ plasma, NH₃/He plasma, NH₂/Ar plasma, He plasma, Ar plasma, H₂ plasma, H₂/He plasma, H₂/organic amine plasma, and mixtures thereof. N₂ may also be utilized as a reducing agent when treated with plasma. For instance, the plasma may be generated with a power ranging from about 50 W to about 500 W, preferably from about 100 W to about 200 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

For example, the co-reactant may be introduced into a direct plasma reactor, which generates plasma in the reaction chamber, to produce the plasma-treated reactant in the reaction chamber. The co-reactant may be introduced and held in the reaction chamber prior to plasma processing. Alternatively, the plasma processing may occur simultaneously with the introduction of the reactant.

Alternatively, the plasma-treated co-reactant may be produced outside of the reaction chamber, for example, a remote plasma to treat the co-reactant prior to passage into the reaction chamber.

Also disclosed are methods for forming metal-containing layers on a substrate using a vapor deposition process. Applicants believe that the disclosed film forming compositions are suitable for ALD. More particularly, the disclosed film forming compositions are capable of surface saturation, self-limited growth per cycle, and perfect step coverage on aspects ratios ranging from approximately 2:1 to approximately 200:1, and preferably from approximately 60:1 to approximately 150:1. Additionally, the disclosed film forming compositions have high decomposition temperatures, indicating good thermal stability to enable ALD. The high decomposition temperatures permit ALD at higher temperatures, resulting in films having higher purity.

The disclosed metal-containing precursor and one or more co-reactants may be introduced into the reaction chamber simultaneously (CVD), sequentially (ALD), or in other combinations. For example, the disclosed metal-containing precursor may be introduced in one pulse and two additional metal sources may be introduced together in a separate pulse [modified atomic layer deposition]. Alternatively, the reaction chamber may already contain the reactant prior to introduction of the metal-containing precursor. The reactant may be passed through a plasma system localized or remotely from the reaction chamber, and decomposed to radicals. Alternatively, the metal-containing precursor may be introduced to the reaction chamber continuously while other metal sources are introduced by pulse (pulsed-CVD). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s. In another alternative, the metal-containing precursor and one or more reactants may be simultaneously sprayed from a shower head under which a susceptor holding several wafers is spun (spatial ALD).

The disclosed film forming compositions may be used to deposit metal-containing films using any deposition methods known to those of skill in the art. Examples of suitable deposition methods include CVD or ALD with or without plasma enhancement. More specifically, exemplary of suitable deposition methods include without limitation, thermal ALD, plasma enhanced ALD (PEALD), spatial isolation ALD, temporal ALD, selective or not ALD, hot-wire ALD (HWALD), radicals incorporated ALD, and combinations thereof. The deposition method is preferably ALD, PE-ALD, or spatial ALD in order to provide suitable step coverage and film thickness control. Exemplary CVD methods include metal-organic CVD (MOCVD), thermal CVD, pulsed CVD (PCVD), low pressure CVD (LPCVD), sub-atmospheric CVD (SACVD) or atmospheric pressure CVD (APCVD), hot-wire CVD or hot filament CVD (also known as cat-CVD, in which a hot wire serves as an energy source for the deposition process), hot wall CVD, cold wall CVD, aerosol assisted CVD, direct liquid injection CVD, combustion CVD, hybrid physical-CVD, metalorganic CVD, rapid thermal CVD, photo-initiated CVD, laser CVD, radicals incorporated CVD, plasma enhanced CVD (PECVD) including but not limited to flowable PECVD, and combinations thereof.

In one non-limiting exemplary ALD type process, the vapor phase of a metal-containing precursor is introduced into the reaction chamber, where it is contacted with a suitable substrate. Excess metal-containing precursors may then be removed from the reaction chamber by purging and/or evacuating the reaction chamber. An oxygen source is introduced into the reaction chamber where it reacts with the absorbed metal-containing precursor in a self-limiting manner. Any excess oxygen source is removed from the reaction chamber by purging and/or evacuating the reaction chamber. If the desired film is a metaloxide film, this two-step process may provide the desired film thickness or may be repeated until a film having the necessary thickness has been obtained.

In yet another alternative, a metal-containing film may be deposited by the flowable PECVD method disclosed in U.S. Pat. App. Pub. No. 2014/0051264 using the disclosed metal-containing precursors and a radical nitrogen- or oxygen-containing co-reactant. The radical nitrogen- or oxygen-containing co-reactant, such as NH₃ or H₂O respectively, is generated in a remote plasma system, The radical co-reactant and the vapor phase of the disclosed precursors are introduced into the reaction chamber where they react and deposit the initially flowable film on the substrate. Applicants believe that the nitrogen atom of the disclosed compounds help to further improve the flowability of the deposited film, resulting in films having less voids.

Also disclosed are methods of using the disclosed metal-containing precursors in casting deposition methods, such as spin coating (i.e., SOD), spray coating, dip coating or slit coating techniques. The disclosed methods provide for the use of the metal-containing film forming composition for deposition of metal-containing films. The method disclosed includes: providing a substrate; applying a liquid form of the disclosed metal-containing film forming composition containing the disclosed metal-containing precursor on a substrate; and forming the metal-containing layer on the substrate. As discussed previously, the liquid form of the disclosed metal-containing film forming composition may be a neat solution of the metal-containing precursors or a mixture of the metal-containing precursor with a solvent and optional pH adjusters or surfactants. In one embodiment, the metal-containing film forming compositions may be supplied in a blend with a solvent suitable for the SOD, for example, the metal-containing film forming compositions may be mixed with toluene, ethyl benzene, xylene, mesitylene, decane, dodecane, octane, hexane, pentane, tertiary amines, acetone, tetrahydrofuran, ethanol, ethylmethylketone, or 1,4-dioxane, to form a liquid form of the metal-containing film forming composition for the SOD.

The liquid form of the disclosed metal-containing film forming composition may be applied directly to the center of the substrate or may be applied to the entire substrate by spraying. When applied directly to the center of the substrate, the substrate may be spun to utilize centrifugal forces to evenly distribute the composition over the substrate. Alternatively, the substrate may be dipped in the Metal-containing film forming composition. The resulting film may be dried at an appropriate temperature for a period of time to vaporize any solvent or volatile components of the film. One of ordinary skill in the art would recognize the appropriate temperature selection based on the solvent to be evaporated. During the vaporization process, a mist of water may be sprayed onto the substrate to promote the hydrolysis reaction of the film.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the metal-containing film may be exposed to a temperature ranging from approximately 200° C. and approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 600° C. for less than 3600 seconds under a H-containing atmosphere, The resulting film may contain fewer impurities and therefore may have improved performance characteristics. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the metal-containing film.

### Examples

The following non-limiting examples are provided to further illustrate embodiments of the invention. However, the examples are not intended to be all inclusive and are not intended to limit the scope of the inventions described herein.

Thermogravimetric (TG) analysis was performed at 25° C. to 500° C. under atmospheric (1000 mBar, N₂ 220 sccm) or vacuum (20 mBar, N₂ 20 sccm) by Aluminum open cup. Vapor pressure (VP) was determined by TG analysis from 60° C. to 180° C. with Naphthalene as external standard. Differential scanning calorimetry (DSC) was measured with Au-coated closed pan up to 300° C., or 400° C.

Bis(alkyl-arene)metal complexes were prepared by reported methods; V. S. Asirvatham et al. Organometallics 2001 20, 1687-1688; L. Calucci et at Dalton Trans. 2006, 4228-4234.

### Comparative Example 1—Thermal Properties of Pure Mo(ethyl-benzene)₂ vs Commercial Mo(ethyl-benzene)₂

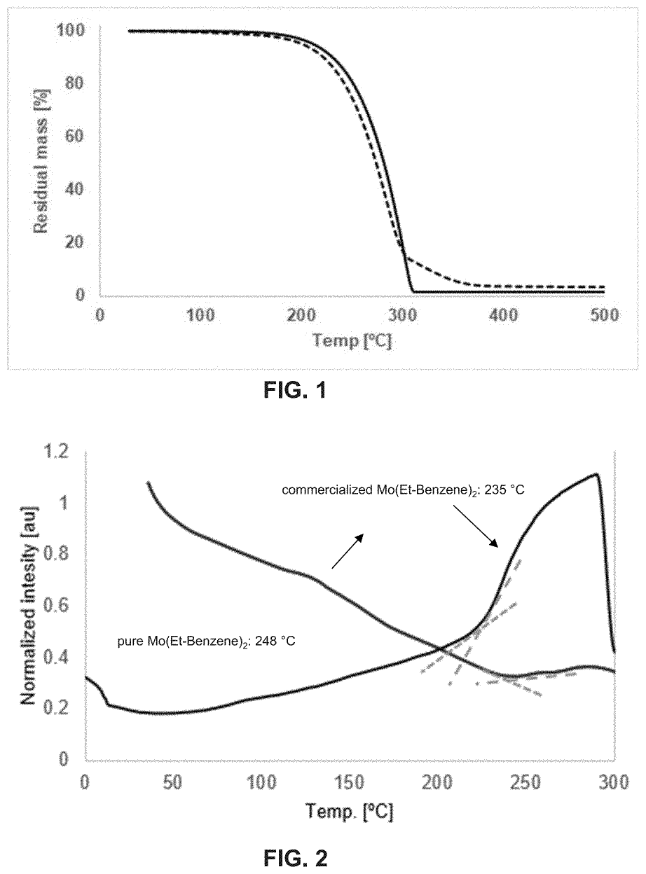

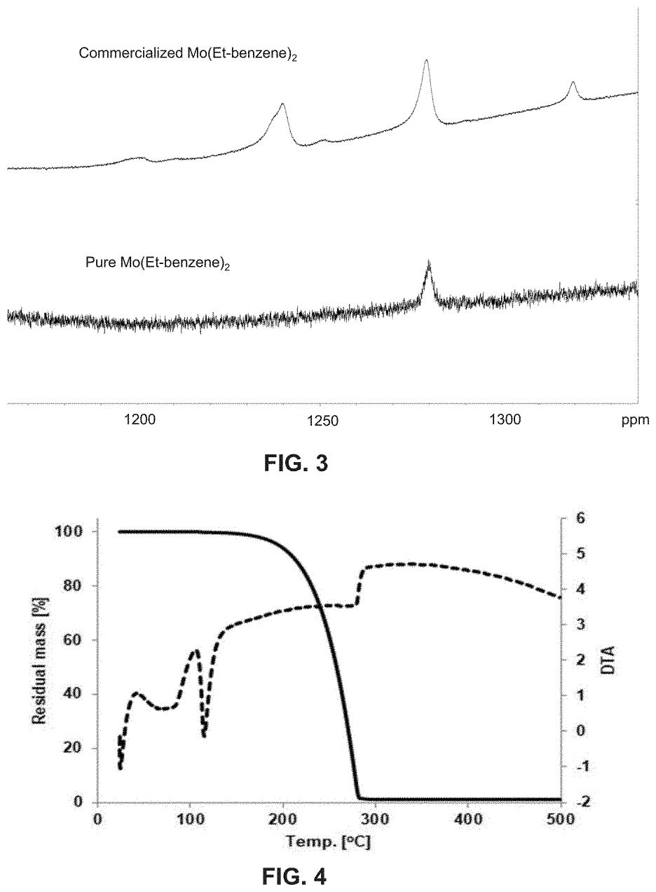

FIG. 1 is TGA of Mo(ethyl-benzene)₂. The solid line is the TGA curve of in-house synthesized pure Mo(ethyl-benzene)₂, and the dashed line is the TGA curve of commercially available Mo(ethyl-benzene)₂. The commercially available Mo(ethyl-benzene)₂ (CAS No.: 32877-00-2) is [(C₂H₅)ₓC₆H₍₆₋ₓ₎]₂Mo, a mixture of (C₂H₅)ₓC₆H₍₆₋ₓ₎ where x=0-4. FIG. 2 shows the DSC of Mo(ethyl-benzene)₂. Thus, pure Mo(alkylarene)₂ may be expected to have better thermal properties than mixture compounds, such as commercially available Mo(ethyl-benzene)₂. As a result, pure Mo(alkylarene)₂, may exhibit a higher stability when stored in a canister, or heated canister from where the vapors are generated before being directed to the reaction furnace. The decomposition temperature of the commercially available Mo(Et-benzene) is lower than the pure product on the TG experiment, as shown by the tail in its evaporation pattern at high temperatures. It may extend the lifetime of the product or allow the user to heat the product at higher temperatures, hence generating a higher dose of vapors, which may allow it to deposit films faster. Productivity is increased and cost is decreased. FIG. 3 is an overlay of ⁹⁵Mo NMR of pure Mo(ethylbenzene)₂ in comparison to the mixture of commercially available Mo(ethylbenzene)₂.

### Example 1—Thermal Properties of Pure Mo(mesitylene)₂

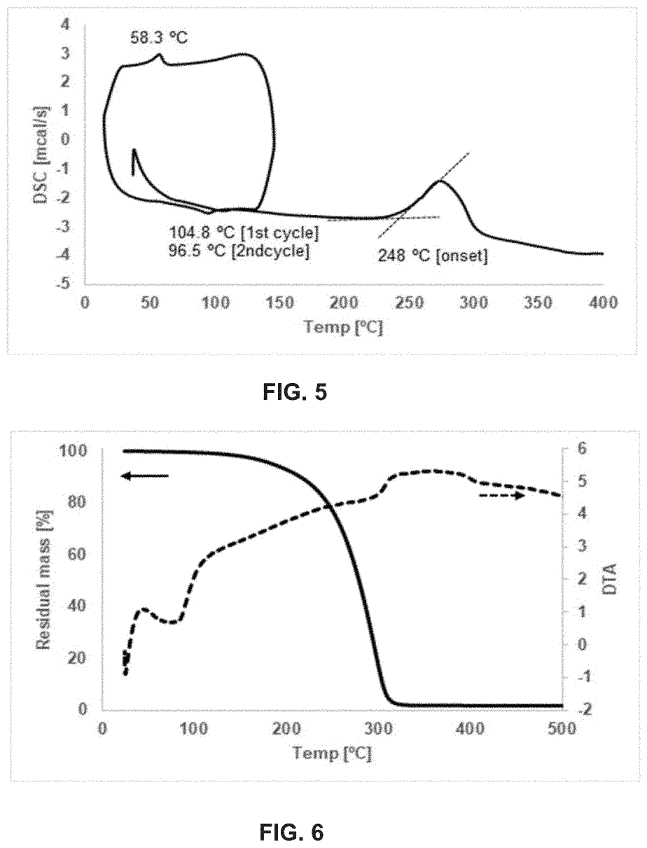

FIG. 4 is atmospheric TG analysis of Mo(mesitylene)₂. It shows that it evaporates without decomposition under these conditions. The vapor pressure of the compound is 1 Torr at 143° C. DSC results (FIG. 5) of Mo(mesitylene)₂ exhibit a melting point at about 105° C. and the decomposition point at 248° C. Results are compared with other compounds in Table 1 below.

### Example 2—Thermal properties of pure Mo(1,3,5-Et₃-benzene)₂

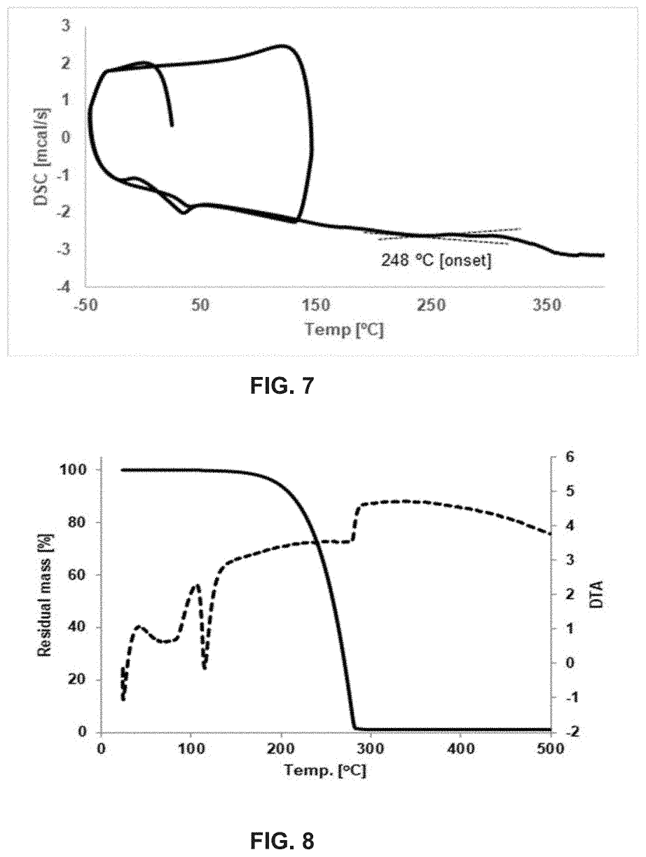

The obtained molecule is an oil at ambient temperature. FIG. 6 is atmospheric TG analysis of Mo(1,3,5-Et₃-benzene)₂. It shows that it evaporates without decomposition under these conditions. The vapor pressure of the compound is 1 torr at 151° C. DSC results (FIG. 7) of Mo(1,3,5-Et₃-benzene)₂ exhibit a decomposition point at 246° C. Results are compared with other compounds in Table 1 below.

### Example 3—Thermal Properties of Pure Mo(m-xylene)₂

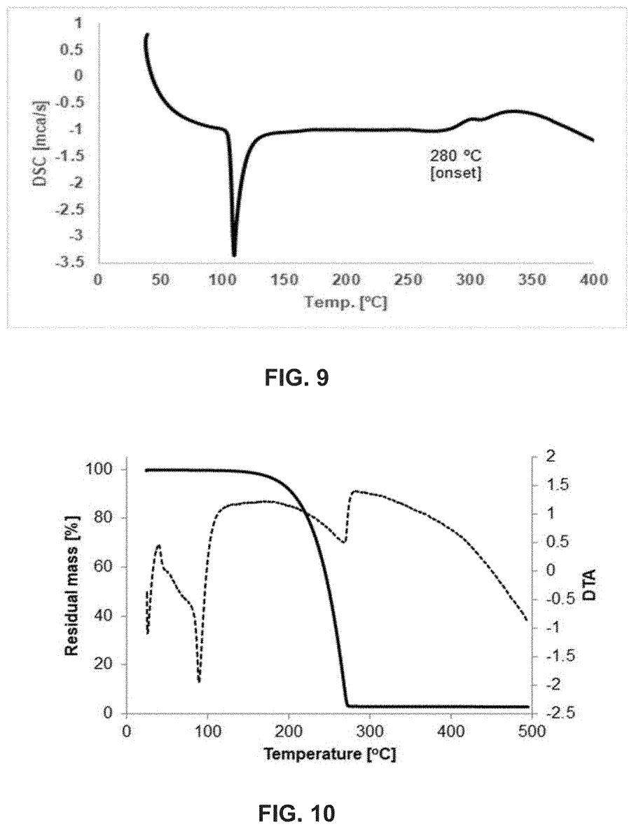

FIG. 8 shows the atmospheric TG analysis of Mo(m-xylene)₂. It shows that it evaporates without decomposition under these conditions. The vapor pressure of the compound is 1 torr at 130° C. DSC results (FIG. 9) of Mo(m-xylene)₂ exhibit a melting point at ˜110° C. and a decomposition point at 280° C. Results are compared with other compounds in Table 1 below.

### Example 4—Thermal Properties of Pure Mo(toluene)₂

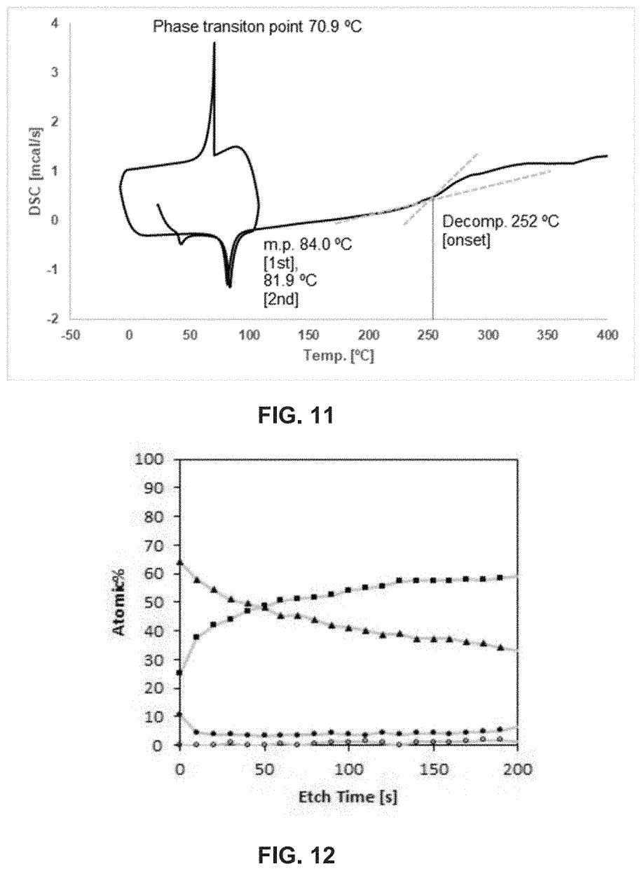

FIG. 10 is atmospheric TG analysis of Mo(toluene)₂. The vapor pressure of this compound is 1 Torr at 133° C. DSC results (FIG. 11) of Mo(toluene)₂ exhibit a melting point at 72° C. and a decomposition point at 252° C. Results are compared with other compounds in Table 1 below.

TABLE 1

| | | 1 torr | Decomposition |
|---|---|---|---|
| | Melting point | temperature | temperature |
| Molecule | (° C.) | (° C.) | (DSC) (° C.) |
| pure Mo(ethyl-benzene)₂ | <20 | 131 | 248 |
| Commercially available | <20 | 123 | 235 |
| Mo(ethyl-benzene)₂ | | | |
| (mixture) | | | |
| Mo(mesitylene)₂ | 105 | 143 | 248 |
| Mo(1,3,5-Et₃-benzene)₂ | <20 | 151 | 248 |
| Mo(m-xylene)₂ | 110 | 130 | 280 |
| Mo(toluene)₂ | 72 | 133 | 252 |

### Example 5—Mo Containing Film Deposition by Mo(m-xylene)₂ without Co-Reactant

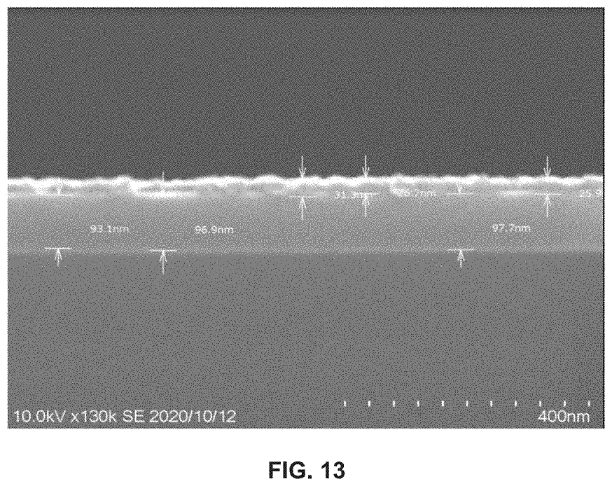

Mo(m-xylene)₂ was heated at 120° C., and its vapors provided to the reaction chamber by supplying 150 sccm Ar for 30 minutes. At this time, the chamber was heated at 420° C. The obtained film was analyzed by XPS and SEM. These indicated that deposited film has Mo and C in film, and that thicker is 25.9 to 31 nm. FIG. 12 is atomic profile of deposited film by XPS of chemical vapor deposition of Mo(m-xylene)₂ [Square: Molybdenum, triangle: Carbon, filled-circle: oxygene, and open circle: Silicon]. FIG. 13 is SEM data of pyrolysis deposition of Mo(m-xylene)₂.

### Example 6—Mo Containing Film Deposition by Mo(m-xylene)₂ with H₂ as Co-Reactant

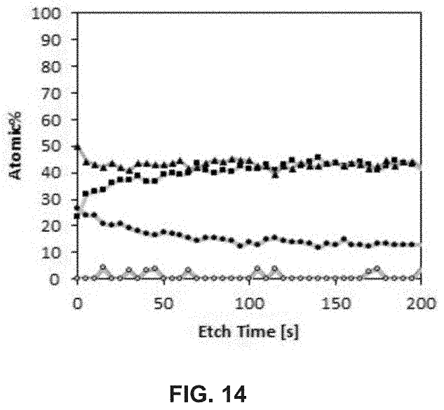

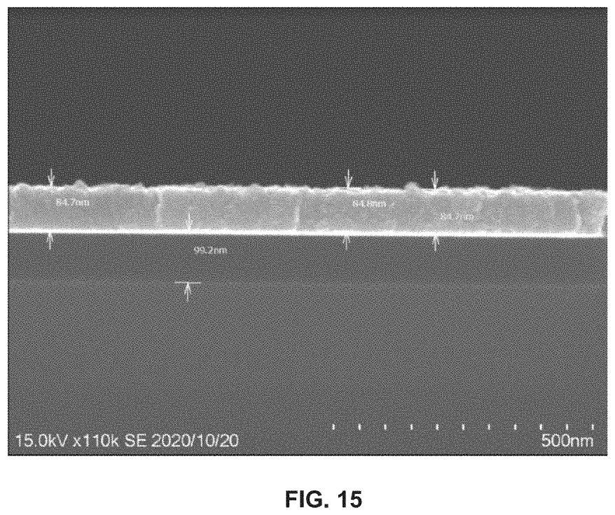

Mo(m-xylene)₂ was heated at 120° C., and its vapors provided to the reaction chamber by supplying 150 sccm Ar for 30 minutes. The chamber was heated at 420° C., and 50 sccm of H₂ as co-reactant was provided for the reaction chamber. The obtained film was analyzed by XPS and SEM. These indicated that deposited film has Mo and C in film, and that thicker is 84.7 to 84.8 nm. FIG. 14 is atomic profile of deposited film by XPS of chemical vapor deposition of Mo(m-xylene)₂ with H₂ [Square: Molybdenum, triangle: Carbon, filled-circle: oxygene, and open circle: Silicon]. FIG. 15 is SEM data of chemical vapor deposition of Mo(m-xylene)₂ with H₂.

### Prophetic Example 1—Pure Mo films obtained with Mo(alkyl-arene)₂

More highly pure or less contaminated Mo films may be obtained when a co-reactant like hydrogen, other reducing agents, other co-reactant, or their combinations are used at deposition temperatures ranging from 200° C. to 400° C. Exemplary Mo(alkyl-arene)₂ includes Mo(m-xylene)₂, Mo(toluene)₂ Mo(1,3,5-Et₃-benzene)₂ Mo(mesitylene)₂Mo(ethyl-benzene)₂.

### Prophetic Example 2—Pure W Films Obtained with W(alkyl-arene)₂

Pure W(alkyl-arene)₂ was synthesized following a reported synthesis route. When this molecule is used in CVD mode, it is expected that pure W films can be obtained when a co-reactant like hydrogen or other reducing agents are used at deposition temperatures ranging from 200° C. to 400° C. Exemplary W(alkyl-arene)₂ include W(m-xylene)₂, W(toluene)₂ W(1 ,3,5-Et₃-benzene)₂ W(mesitylene)₂ W(ethyl-benzene)₂.

### Prophetic Example 3—Pure Cr Films Obtained with Cr(alkyl-arene)₂

Pure Cr(alkyl-arene)₂ was synthesized following a reported synthesis route. When this molecule is used in CVD mode, it is expected that pure W films can be obtained when a co-reactant like hydrogen or other reducing agents are used at deposition temperatures ranging from 200° C. to 400° C. Exemplary Cr(alkyl-arene)₂ include Cr(m-xylene)₂, Cr(toluene)₂ Cr(1,3,5-Et₃-benzene)₂ Cr(mesitylene)₂ Cr(Ethyl-benzene)₂.

Although the subject matter described herein may be described in the context of illustrative implementations to process one or more computing application features/operations for a computing application having user-interactive components the subject matter is not limited to these particular embodiments. Rather, the techniques described herein can be applied to any suitable type of user-interactive component execution management methods, systems, platforms, and/or apparatus.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

1. A method for forming a metal-containing film on a substrate, the method comprising the steps of:
exposing the substrate to a vapor of a film forming composition that contains a metal-containing precursor; and
depositing at least part of the metal-containing precursor onto the substrate to form the metal-containing film on the substrate through a vapor deposition process,
wherein the metal-containing precursor is a pure M(alkyl-arene)₂ precursor selected from Mo(m-xylene)₂, Mo(toluene)₂, Mo(1,3,5-Et₃-benzene)₂, or Mo(mesitylene)₂,
wherein a purity of the pure M(alkyl-arene)₂ precursor ranges from approximately 99% w/w to approximately 99.999% w/w.

2.-7. (canceled)

8. The method of claim 1, wherein a decomposition temperature of the pure M(alkyl-arene)₂ precursor is higher than approximately 240° C.

9. The method of claim 1, wherein a deposition temperature ranges from approximately 20° C. and approximately 600° C.

10. The method of claim 1 wherein a deposition pressure ranges from about 0.001 mTorr to about 760 Torr.

11. The method of claim 1, wherein the metal-containing film is a pure metal, metal carbide, metal oxide, metal nitride film or combinations thereof.

12. The method of claim 1, wherein the film forming composition includes an inert carrier gas selected from N₂, He, Ne, Ar, Kr, Xe, or combinations thereof.

13. The method of claim 1, further comprising the step of exposing the substrate to a co-reactant.

14. The method of claim 13, further comprising the step of plasma treating the co-reactant.

15. The method of claim 13, wherein the co-reactant is halosilane, polyhalodisilane (halo=F, Cl, Br, I), organohalide selected from SiH₂Cl₂, SiH₂I₂, SiHCl₃, SiCl₄, SiBr₄, Si₂Cl₆, Si₂Br₆, Si₂HCl₅, Si₃Cl₈, CH₂I₂, CH₃I, C₂H₅I, C₄H₉I, or C₆H₅I.

16. The method of claim 13, wherein the co-reactant is selected from O₂, O₃, H₂O, H₂O₂, N₂O, NO, NO₂, O. or OH. radicals, or mixtures thereof.

17. The method of claim 13, wherein the co-reactant is selected from H₂, NH₃, N₂H₄, Me-N₂H₄, Me₂N₂H₂, SiH₄, Si₂H₆, Si₃H₈, Si₄H₁₀, SiH₂Me₂, SiH₂Et₂, N(SiH₃)₃, NH₃ radicals, H₂ radicals, or combination thereof.

18. The method of claim 13, the co-reactant is selected from NH₃, NO, N₂O, hydrazines, N₂ plasma, N₂/H₂ plasma, NH₃ plasma, amines and combinations thereof.

19. The method of claim 1, wherein the vapor deposition process is an ALD process or a CVD process.

20. The method of claim 1, wherein the substrate is selected from a Si-containing substrate, a metal substrate, a metal-containing substrate or a powder substrate.
